(19) United States
(12) Patent Application Publication
(10) Pub. No.: US 2006/0138478 A1
(43) Pub. Date: Jun. 29, 2006

(54) Semiconductor device and method of forming same

(75) Inventors: Gyoung-Ho Buh, Gyeonggi-do (KR); Yu-Gyun Shin, Gyeonggi-do (KR); Chang-Woo Ryoo, Gyeonggi-do (KR); Soo-Jin Hong, Gyeonggi-do (KR); Jin-Wook Lee, Gyeonggi-do (KR); Guk-Hyon Yon, Gyeonggi-do (KR)

Correspondence Address: MYERS BIGEL SIBLEY & SAJOVEC, PO BOX 37428, RALEIGH, NC, 27627, US

(73) Assignee: Samsung Electronis Co., Ltd.

(21) Appl. No.: 11/318,827

(22) Filed: Dec. 27, 2005

(30) Foreign Application Priority Data
Dec. 29, 2004 (KR) 10-2004-0115406

(51) Int. Cl. H01L 29/76; H01L 29/788; H01L 29/94

(52) U.S. Cl. 257/288; 257/408; 257/344; 257/321; 257/315; 257/313

(57) ABSTRACT

A semiconductor device includes a gate pattern disposed on a semiconductor substrate, a gate spacer disposed on both sidewalls of the gate pattern, and a fixed charge layer disposed in the semiconductor substrate below the gate spacer. Elements generating fixed charges are injected into the fixed charge layer. A layer in which carriers induced by the fixed charge layer are accumulated is disposed below the fixed charge layer. The elements are segregated to a substrate of the semiconductor substrate from the inside of the semiconductor substrate by heat.

### RELATED APPLICATION

This application claims priority from Korean Patent Application No. 2004-115406, filed on Dec. 29, 2004 in the Korean Intellectual Property Office, the disclosure of which is incorporated herein in its entirety by reference.

### FIELD OF THE INVENTION

The present invention relates generally to semiconductor devices and, more particularly, to semiconductor devices having source/drain regions and methods of forming the same.

### BACKGROUND OF THE INVENTION

A MOS transistor of a semiconductor device may include a pair of source/drain regions disposed at a semiconductor substrate and spaced apart from each other and a gate electrode disposed over a channel region between the pair of the source/drain regions. A typical MOS transistor includes a source/drain region of a lightly doped drain (LDD) structure to reduce hot carrier effects. A lightly doped region is formed at a portion of a source/drain region adjacent to a channel region, so that concentration of an electric field is relaxed to reduce hot carrier effects. A method of forming a MOS transistor having such a structure will now be described with reference to FIG. 1.

As illustrated in FIG. 1, a gate pattern 5 is formed on a semiconductor substrate 1. The gate pattern 5 includes a gate oxide layer 2, a gate electrode 3, and a capping pattern 4, which are stacked in the order named. Using the gate pattern 5 as a mask, impurities of a low dose are implanted to form a lightly doped layer 6.

A gate spacer 7 is formed on both sidewalls of the gate pattern 5. Using the gate pattern 5 and the gate spacer 7 as a mask, impurities of a high dose are implanted to form a heavily doped layer 8. As a result, source/drain regions 9 formed at opposite sides adjacent to the gate pattern 5 have an LDD structure including the heavily and lightly doped layers 6 and 8.

With the recent trend toward finer semiconductor devices, a linewidth of the gate pattern 5 is decreasing. Accordingly, channel length of a MOS transistor is gradually reduced to result in severe short channel effects. Due to the severe short channel effects, characteristics of the MOS transistor are degraded. In case of, for example, an NMOS transistor, the gradual reduction of the channel length causes a threshold voltage roll-off of the MOS transistor. Since turn-off current of the MOS transistor increases due to the threshold voltage roll-off, leakage current of a semiconductor device may increase or malfunction of a semiconductor device may arise.

With the ever-increasing requirement for higher operating speed of semiconductor devices, what is required is a MOS transistor which outputs lots of turn-on current. However, as a doping concentration of the lightly doped layer 6 is lowered so as to suppress the hot carrier effects and/or the short channel effects, the turn-on current of the MOS transistor decreases due to a high resistance of the lightly doped layer 6.

One approach to increasing turn-on current is to increase the doping concentration of the lightly doped layer 6 increases as high as the heavily doped layer 8. Unfortunately, this approach may make the short channel effects severe.

### SUMMARY OF THE INVENTION

Exemplary embodiments of the present invention are directed to a semiconductor device and a method of forming the same. In an exemplary embodiment, a semiconductor device may include a gate pattern disposed on a semiconductor substrate; a gate spacer disposed on both sidewalls of the gate pattern; a fixed charge layer disposed in the semiconductor substrate below the gate spacer; and an inversion layer disposed below the fixed charge layer, the inversion layer being induced by the fixed charge layer. Elements generating fixed charges are injected into the charge storage layer and segregated to a surface of the semiconductor substrate from the inside of the semiconductor substrate by heat.

In another exemplary embodiment, a semiconductor device may include a gate pattern disposed on a semiconductor substrate; a gate spacer disposed on both sidewalls of the gate pattern; a fixed charge layer disposed in the semiconductor substrate below the gate spacer; a lightly doped layer disposed in the semiconductor substrate below the gate spacer to overlap the fixed charge layer and having a lower bottom surface than the fixed charge layer; and a carrier accumulating layer disposed at the lightly doped layer below the fixed charge layer and induced by the fixed charge layer. Elements generating fixed charges are injected into the fixed charge layer and segregated to a surface of the semiconductor substrate from the inside of the semiconductor substrate.

In another exemplary embodiment, a method may include forming a gate pattern on a semiconductor substrate, wherein the semiconductor substrate at opposite sides adjacent to the gate pattern is exposed; injecting element ions generating fixed charges into the exposed semiconductor substrate, using the gate pattern as a mask, to form a fixed charge layer; and forming a gate spacer on both sidewalls of the gate pattern. A layer in which carriers induced by the fixed charge is accumulated is formed below the fixed charge layer, and the elements are segregated to a surface of the semiconductor substrate from the inside of the semiconductor substrate by heat.

### BRIEF DESCRIPTION OF THE DRAWINGS

FIG. 1 is a cross-sectional view of a conventional MOS transistor.

FIG. 2 is a cross-sectional view of a semiconductor device according to a first embodiment of the present invention.

FIG. 3 is a graph for explaining characteristics of elements injected to a fixed charge layer shown in FIG. 2.

FIG. 4 is a graph for explaining characteristics of a semiconductor device according to the first embodiment of the present invention.

FIG. 5A is a cross-sectional view of a modified version of a semiconductor device according to the first embodiment of the present invention.

FIG. 5B is a cross-sectional view of another modified version of a semiconductor device according to the first embodiment of the present invention.

FIG. 6 and FIG. 7 are cross-sectional views for explaining a method of forming a semiconductor device according to the first embodiment of the present invention.

FIG. 8 is a cross-sectional view for explaining a method of forming modified versions of a semiconductor device according to the first embodiment of the present invention.

FIG. 9 is a cross-sectional view of a semiconductor device according to a second embodiment of the present invention.

FIG. 10A is a cross-sectional view of a modified version of a semiconductor device according to the second embodiment of the present invention.

FIG. 10B is a cross-sectional view of another modified version of a semiconductor device according to the second embodiment of the present invention.

FIG. 11 and FIG. 12 are cross-sectional views for explaining a method of forming a semiconductor device according to the second embodiment of the present invention.

FIG. 13 is a cross-sectional view for explaining a method of forming modified versions of a semiconductor device according to the second embodiment of the present invention.

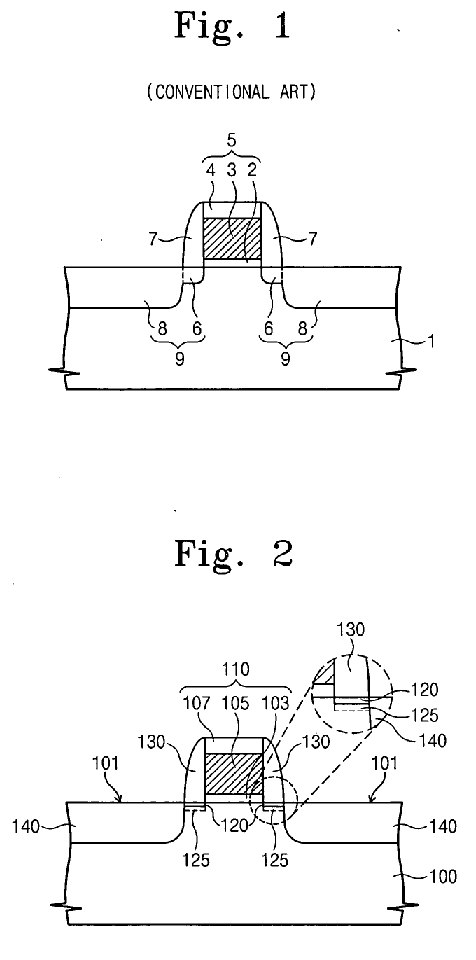

### DETAILED DESCRIPTION OF THE INVENTION

The present invention will now be described more fully hereinafter with reference to the accompanying drawings, in which preferred embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the height of layers and regions are exaggerated for clarity. It will also be understood that when a layer is referred to as being “on” another layer or substrate, it can be directly on the other layer or substrate, or intervening layers may also be present. Like numbers refer to like elements throughout.

FIG. 2 is a cross-sectional view of a semiconductor device according to a first embodiment of the present invention. Referring to FIG. 2, a gate pattern 110 is disposed on a semiconductor substrate 100 doped with impurities of a first conduction type. The gate pattern 110 may include a gate insulation layer 103, a gate electrode 105, and a capping pattern 107, which are stacked in the order named. The gate insulation layer 103 may be made of thermal oxide. The gate electrode 105 may be made of material selected from the group consisting of doped polysilicon, metal (e.g., tungsten or molybdenum), conductive metal nitride (e.g., titanium nitride or tantalum nitride), metal silicide (e.g., tungsten silicide, cobalt silicide, nickel silicide or titanium nitride), and combinations thereof. The capping pattern 107 may be an insulation pattern made of material selected from the group consisting of silicon oxide, silicon oxynitride, and silicon nitride.

A gate spacer 130 is disposed on both sidewalls of the gate pattern 110. The gate spacer 130 includes an insulation layer. Particularly, the gate spacer 130 includes an insulation layer having a lower dielectric constant than silicon nitride. For example, the gate spacer 130 may include silicon oxide, silicon carbide (SiC) or silicon oxycarbide (SiOC).

A fixed charge layer 120 is disposed in a semiconductor substrate 100 below the gate spacer 130. The fixed charge layer 120 is disposed exactly below a substrate 101 of the semiconductor substrate 100 (hereinafter referred to as “substrate surface”). Namely, a top surface of the fixed charge layer 120 is planar with the substrate surface 101 and a bottom surface thereof has a predetermined depth from the substrate surface 101.

The fixed charge layer 120 is a layer into which elements for generating positive fixed charges or negative fixed charges are injected. Thus, the fixed charge layer 120 is charged with positive or negative charges. The elements are segregated to the substrate surface 101 from the inside of the semiconductor substrate 100 by heat.

An inversion layer 125 induced by the fixed charge layer 120 is disposed below the fixed charge layer 120. Carriers having opposite type to charges of the fixed charge layer 120 are accumulated in the inversion layer 125. In a case where the fixed charge layer 120 is charged with, for example, negative charges, holes are accumulated in the inversion layer 125. To the contrary, in a case where the fixed charge layer 120 is charged with positive charges, electrons are accumulated in the inversion layer 125. The fixed charge layer 120 is charged with charges having the same type as major carriers of the semiconductor substrate 100. Thus, the inversion layer 125 is charged with carriers having an opposite type to the major carriers of the semiconductor substrate 100 to be laid in an inversion state.

An impurity-doped layer 140 is disposed at one side of the inversion layer 125 which is opposed to the gate pattern 110. That is, the inversion layer 125 is disposed between a channel region below the gate pattern 110 and the impurity-doped layer 140. The impurity-doped layer 140 is aligned with the gate spacer 130 and doped with impurities of a second conduction type that is opposite to the conduction type of the impurities of the semiconductor substrate 100. The inversion layer 125 is electrically connected to the impurity-doped layer 140. An impurity concentration of the impurity-doped layer 140 may be a high concentration.

The inversion layer 125 and the impurity-doped layer 140 constitute a source/drain region. The gate pattern 110 and the source/drain region constitute a MOS transistor.

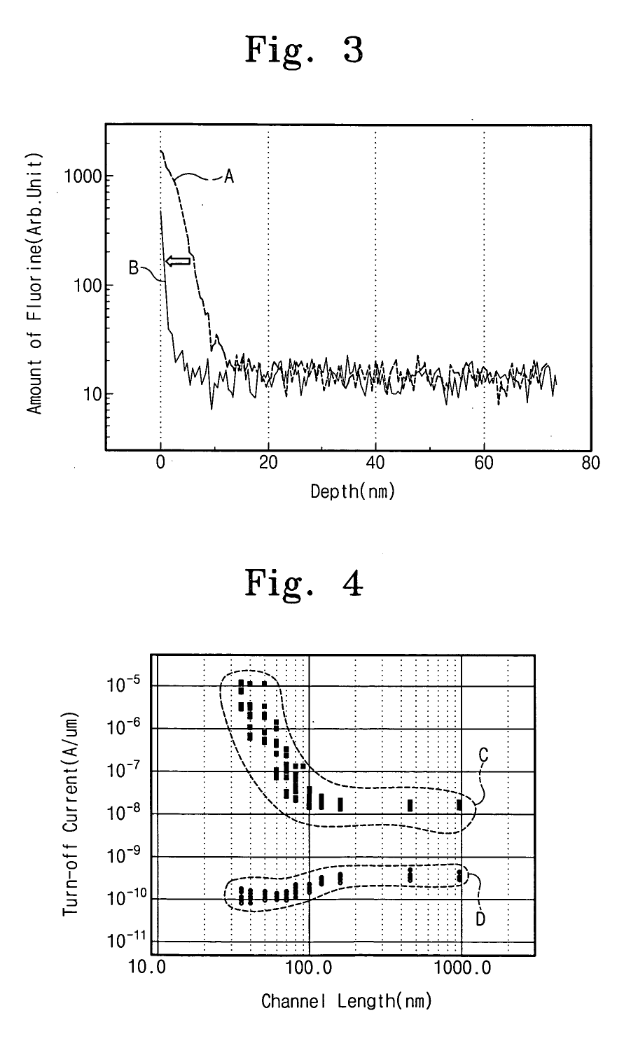

In a case where the semiconductor substrate 100 is doped with N-type impurities and the impurity-doped layer 140 is doped with P-type impurities, the fixed charge layer 120 is charged with negative charges to accumulate holes in the inversion layer 125. In this case, elements in the fixed charge layer 120 charged with the negative charges are fluorines. The fluorines generate negative charges and are segregated to the substrate surface 101 from the inside of the semiconductor substrate 100 by heat. The segregation characteristic of the fluorines will now be described with reference to FIG. 3.

FIG. 3 illustrates a graph for explaining characteristics of elements injected to the fixed charge layer shown FIG. 2. In FIG. 3, an X-axis of the graph represents a depth from a surface of a silicon substrate and a Y-axis of the graph represents the amount of fluorines measured according to the depth.

Referring to FIG. 3, the graph is based on test data. First, samples 1 and 2 were prepared for test. Fluorine ions were implanted into a silicon substrate of the sample 1 at a dose of 2.5E15/cm² with energy of 3 KeV. The sample 1 was not subjected to an annealing process.

Fluorine ions were implanted into a silicon substrate of the sample 2 under the same condition as the sample 1 (i.e., at a dose of 2.5E15/cm² with energy of 3 KeV). After implanting the fluorine ions into the silicon substrate of the sample 2, the sample 2 was subjected to rapid thermal annealing at a temperature of 1050 degrees centigrade for 10 seconds. Thereafter, the sample 2 was subjected to furnace annealing at a temperature of 680 degrees centigrade for an hour.

In FIG. 3, a dotted line A indicates data obtained by measuring the amount of fluorine of the sample 1 using a secondary ion mass spectrometry apparatus (SIMS apparatus), and a solid line B indicates data obtained by measuring the amount of fluorine of the sample 2 using the SIMS apparatus.

According to the dotted line A, fluorines of the unannealed sample 1 are generally distributed at a depth of about 10 nanometers from a surface of a silicon substrate. On the other hand, according to the solid line B, fluorines of the annealed sample 2 are generally distributed at a depth of about 2.8 nanometers, particularly about 1 nanometer, from a surface of a silicon substrate. To sum up, the dotted line A and the solid line B show that the fluorines are segregated to a surface of a silicon substrate from the inside of the silicon substrate by heat.

In the MOS transistor according to the first embodiment of the present invention, a fixed charge layer 120 is disposed within the semiconductor substrate 100 below the gate space 130 to induce the inversion layer to a lower portion of the fixed charge layer 120. Thus, a junction between the semiconductor substrate 100 and the source/drain region becomes far away from the channel region to reduce short channel effects. Further, the inversion layer 125 electrically connects a channel with the impurity-doped layer 140 to operate the MOS transistor normally.

Elements injected into the fixed charge layer 120 are segregated to the substrate surface 110 by heat. For this reason, the elements sojourn in the fixed charge layer 120 even if heat is supplied to the elements in a subsequent process. Particularly, the elements may be accumulated more adjacently in the substrate surface 110 at a high concentration. As a result, the amount of carriers accumulated in the inversion layer 125 may increase and a temperature margin may increase in subsequent processes following formation of the fixed charge layer 120.

Characteristics of the MOS transistor according to the first embodiment of the present invention will now be described with reference to FIG. 4.

In FIG. 4, an X-axis of a graph represents channel length and a Y-axis of the graph represents turn-off current.

Referring to FIG. 2 and FIG. 4, a first wafer and a second wafer were prepared for checking characteristics of a MOS transistor according to the present invention. Conventional transistors were formed at the first wafer, and MOS transistors according the invention were formed at the second wafer. MOS transistors of the first and the second wafers are all PMOS transistors.

Source/drain regions of the MOS transistors of the first wafer are formed to have lightly and heavily doped layers. A lightly doped layer of the first wafer is formed by implanting boron ions at a dose of 2.5E15/cm² with energy of 0.5 KeV, and a heavily doped layer thereof is formed by implanting boron energy at a dose of 3.0E15/cm² with energy of 2 KeV.

Source/drain regions of the MOS transistors of the second wafer are formed to have the inversion layer 125 and the impurity-doped layer 140. In order to form the inversion layer 125, fluorine ions are implanted into the second wafer at a dose of 2.5E15/cm² with energy of 3 KeV to form a fixed charge layer 120. The impurity-doped layer 140 of the second wafer is formed by implanting boron ions at a dose of 3.0E15/cm² with energy of 2 KeV. Since boron ions have smaller sizes than fluorine ions, a bottom surface of the impurity-doped layer 140 is deeper than that of the fixed charge layer 120.

A first group C indicates turn-off currents measured from the MOS transistors of the first wafer, and a second group D indicates turn-off currents measured from the MOS transistors of the second wafer. The first and second groups C and D were established by measuring turn-off currents of ten transistors relative to each channel length.

As illustrated in FIG. 4, the turn-off currents of the first group C increase rapidly as channel length decreases to at least 100 nanometers, which means that short channel effects become severe as channel length decreases. On the other hand, turn-off currents of the second group D are maintained even if channel length decreases to at least 100 nanometers. Data of the second group D show that short channel effects are suppressed even if channel length decreases. As a result, it is understood that short channel effects are suppressed due to the fixed charge layer 120 and the inversion layer 125.

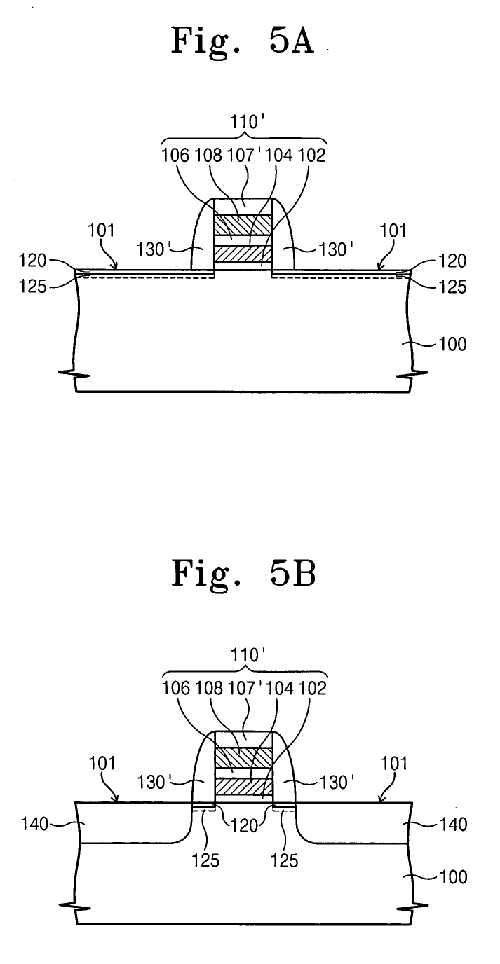

The fixed charge layer 120 and the inversion layer 125 may be applied to other semiconductor devices having a source/drain region, which will be described with reference to FIG. 5A and FIG. 5B.

FIG. 5A is a cross-sectional view of a modified version of the semiconductor device according to the first embodiment of the present invention, and FIG. 5B is a cross-sectional view of another modified version of the semiconductor device according to the first embodiment of the present invention. Referring to FIG. 5A and FIG. 5B, a fixed charge layer 120 and an inversion layer 125 may be applied to a flash memory cell having a charge storage pattern 104.

Specifically, a gate pattern 110′ is disposed on a semiconductor substrate 100. The gate pattern 110′ includes a tunnel insulation layer 102, a charge storage pattern 104, a blocking insulation layer 106, a control gate electrode 108, and a capping pattern 107′, which are stacked in the order named. A gate spacer 130′ is disposed on both sidewalls of the gate pattern 110′.

The fixed charge layer 120 is disposed in the semiconductor substrate 100 below the gate spacer 130′. An inversion layer 125 induced by the fixed charge layer 120 is disposed below the fixed charge layer 120.

The fixed charge layer 120 and the inversion layer 125 may extend along a surface of the semiconductor substrate 100 in an opposite direction to the gate pattern 110′, as illustrated in FIG. 5A. In this case, a source/drain region of the flash memory cell includes only the inversion layer 125.

Alternatively, an impurity-doped layer 140 may be disposed at one side of the fixed charge layer 120 and the inversion layer 125, as illustrated in FIG. 5B. That is, the inversion layer 125 is disposed between a channel region below the gate pattern 110′ and the impurity-doped layer 140. The impurity-doped layer 140 is aligned with the gate spacer 130′. The inversion layer 125 and the impurity-doped layer 140 are electrically connected to each other and constitute a source/drain region of a flash memory cell.

As described above, the flash memory cell has a source/drain region including only the inversion layer 125 or a source/drain region including the inversion layer 125 and the impurity-doped layer 140. Thus, the flash memory cell avoids short channel effects.

Further, elements in the fixed charge layer are segregated to the substrate surface 101 from the semiconductor substrate 100 by heat. For this reason, a temperature margin increases in subsequent processes following formation of the fixed charge layer 120.

The flash memory cell may be applied to NAND flash memory devices where charges are stored in the charge storage pattern 104 by performing F-N tunneling for the tunnel insulation layer 102. A flash memory cell having a source/drain region including only the version layer 125 does not include a contact plug (not shown) connected to a source/drain region of the flash memory cell.

The gate spacer 130′ is made of an insulation material having a lower dielectric constant than silicon nitride. The gate spacer 130′ may be made of one selected from the group consisting of, for example, silicon oxide, silicon carbide, and silicon oxycarbide. The tunnel insulation layer 102 may be made of thermal oxide. The charge storage pattern 104 may be a floating gate made of doped polysilicon. Alternatively, the charge storage pattern 104 may be a trap storage layer having deep-level traps. The storage pattern 104 may be made of, for example, silicon nitride having deep-level traps. The blocking insulation layer 106 may be made of material selected from the group consisting of silicon oxide, oxide-nitride-oxide (ONO), and high-k dielectric such as, for example, aluminum oxide or hafnium oxide. The control gate electrode 108 may be made of the same material as the gate electrode 105 shown in FIG. 2.

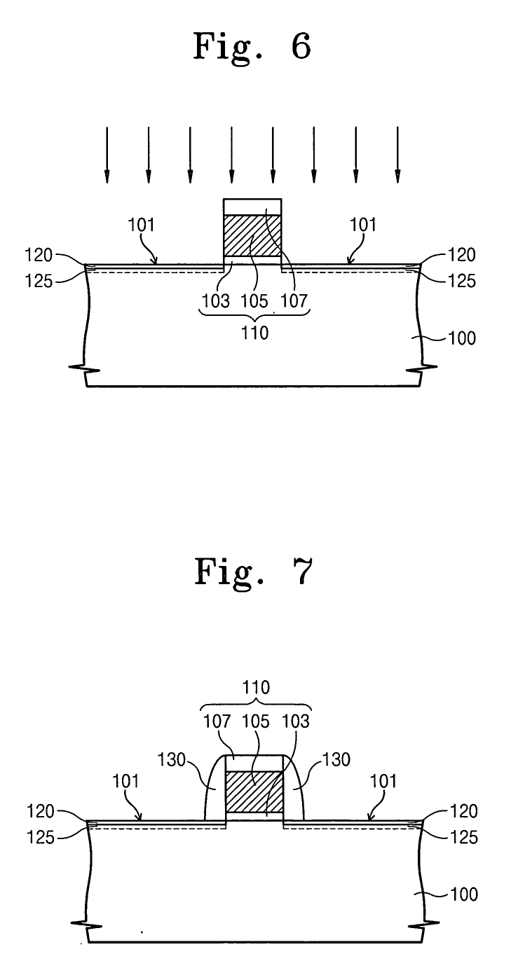

FIG. 6 and FIG. 7 are cross-sectional views for explaining a method of forming a semiconductor device according to the first embodiment of the present invention.

Referring to FIG. 6, a gate pattern 110 is formed on a semiconductor substrate 100 doped with impurities of a first conduction type. The gate pattern 110 includes a gate insulation layer 103, a gate electrode 105, and a capping pattern 107, which are stacked in the order named.

Using the gate pattern 110 as a mask, element ions are implanted to form a fixed charge layer 120 directly below a substrate surface 101 adjacent to opposite sides of the gate pattern 110. While the element ions are implanted, the substrate surface 101 adjacent to the opposite sides of the gate pattern 110 is exposed. The element ions generate negative or positive fixed charges and are segregated to the substrate surface 101 from the inside of the semiconductor substrate 100 by heat.

An inversion layer 125 induced by the fixed charge layer 120 is formed below the fixed charge layer 120. Carriers having an opposite type to charges accumulated in the fixed charge layer 120 are accumulated in the inversion layer 125. Further, carriers having an opposite type to major carriers are accumulated in the inversion layer 125.

In a case where the semiconductor substrate 100 is doped with N-type impurities, the element ions implanted into the fixed charge layer 120 are fluorine ions. The fluorine ions generate negative charges and are segregated to the substrate surface 101 from the inside of the semiconductor substrate 100. Thus, holes are accumulated in the inversion layer 125.

Referring to FIG. 7, a gate spacer 130 is formed on both sidewalls of the gate pattern 110. The gate spacer 130 is made of an insulation material having a lower dielectric constant than silicon nitride. The gate spacer 130 may be made of material selected from the group consisting of, for example, silicon oxide, silicon carbide, and silicon oxycarbide.

Using the gate pattern 110 and the gate spacer 130 as a mask, impurities of a second conduction type are implanted to form an impurity-doped layer 140 shown in FIG. 2. Thus, the impurity-doped layer 140 is aligned with the gate spacer 130. Implanting the impurities into the impurity-doped layer 140 may be done at a high dose of at least 1E15/cm². As a result, the semiconductor device shown in FIG. 2 may be fabricated.

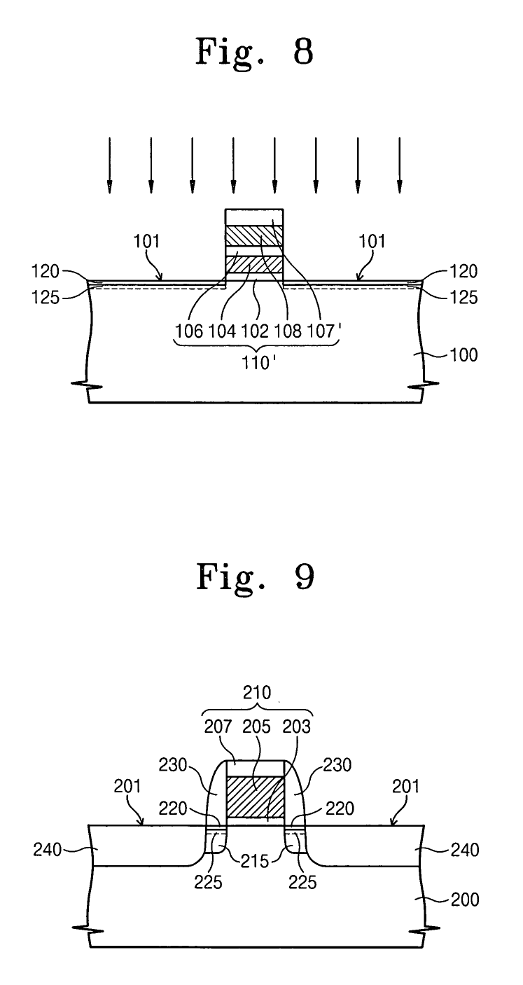

FIG. 8 is a cross-sectional view for explaining a method of forming modified versions of a semiconductor device according to the first embodiment of the present invention. Referring to FIG. 8, a gate pattern 110′ is formed on a semiconductor substrate 100. The gate pattern 110′ includes a tunnel insulation layer 102, a charge storage pattern 104, a blocking insulation layer 106, a control gate electrode 108, and a capping pattern 107′ which are stacked in the order named.

Using the gate pattern 110′ as a mask, element ions are implanted to form a fixed charge layer 120 directly below a substrate surface 101 adjacent to opposite sides of the gate pattern 110′. The element ions generate positive or negative charges and are segregated to the substrate surface 101 from the inside of the semiconductor substrate 100 by heat.

In a case where the semiconductor substrate 100 is doped with N-type impurities, the element ions are fluorine ions.

Thereafter, a gate spacer 130′ shown in FIG. 5A is formed on both sidewalls of the gate pattern 110′ to fabricate a semiconductor device shown in FIG. 5A.

Using the gate pattern 110′ and the gate spacer 130′ shown in FIG. 5A as a mask, impurities are implanted to form an impurity-doped layer 140 shown in FIG. 5B. As a result, a semiconductor device shown in FIG. 5B may be fabricated.

FIG. 9 is a cross-sectional view of a semiconductor device according to a second embodiment of the present invention. Referring to FIG. 9, a gate pattern 210 is disposed on a semiconductor substrate 200 doped with impurities of a first conduction type. The gate pattern 210 includes a gate insulation layer 203, a gate electrode 205, and a capping pattern 207, which are stacked in the order named. A gate spacer 230 is disposed on both sidewalls of the gate pattern 210.

A fixed charge layer 220 is disposed in the semiconductor substrate 200 below the gate spacer 230. The fixed charge layer 220 is disposed directly below a substrate surface 201. The fixed charge layer 220 generates positive or negative fixed charges. Therefore, the fixed charge layer 220 is charged with positive or negative charges. Elements in the fixed charge layer are segregated to the substrate surface 201 to the inside of the semiconductor substrate 200 by heat.

A lightly doped layer 215 overlapping the fixed charge layer 220 is disposed in the semiconductor substrate 200 of the gate spacer 230. The lightly doped layer 215 is doped with impurities of a second conduction type that is different from the type of the impurities doping the semiconductor substrate 200. A bottom surface of the lightly doped layer 215 is spaced apart from the substrate surface 201 to a predetermined depth. The bottom surface of the lightly doped layer 215 is lower than a bottom surface of the fixed charge layer 220.

A carrier accumulating layer 225 is disposed in the lightly doped layer 215 directly below the fixed charge layer 220. The carrier accumulating layer 225 is induced by the fixed charge layer 220. Carriers in the carrier accumulating layer 225 have an opposite type to charges of the fixed charge layer 220.

Particularly, the fixed charge layer 220 is charged with charges having an opposite type to major carriers of the lightly doped layer 215. Therefore, lots of major carriers of the lightly doped layer 215 are accumulated in the carrier accumulating layer 225.

A heavily doped layer 240 is disposed at one side of the lightly doped layer 220 that is opposed to the gate pattern 210. The lightly and heavily doped layer 215 and 240 are doped with impurities of the same type. The heavily doped layer 240 has a higher impurity concentration than the lightly doped layer 215. The lightly and heavily doped layers 215 and 240 are electrically connected to each other. Further, the carrier accumulating layer 225 is electrically connected to the heavily doped layer 240. The lightly doped layer 215 including the carrier accumulating layer 225 and the heavily doped layer 240 constitute a source/drain region. The gate pattern 210 and the source/drain region constitute a MOS transistor.

Alternatively, the MOS transistor may have a source/drain region including only a lightly doped layer 215 having the carrier accumulating layer 225. In this case, the fixed charge layer 220, the carrier accumulating layer 225, and the lightly doped layer 215 extend in an opposite direction to the gate pattern 210.

In a case where the semiconductor substrate 100 is doped with N-type impurities and the lightly and heavily doped layer are doped with P-type impurities, elements in the fixed charge layer 220 are fluorine elements.

The gate insulation layer 203, the gate electrode 205, and the capping pattern 207 may be made of the same materials as the gate insulation layer 103, a gate electrode 105, and a capping pattern 107 shown in FIG. 2, respectively. Further, the gate spacer 230 may be made of the same material as a gate spacer 130, shown in FIG. 2, described in the first embodiment. That is, the gate spacer 230 may be made of an insulation material having a lower dielectric constant than silicon nitride. Accordingly, the gate spacer 230 may be made of material selected from the group consisting of, for example, silicon oxide, silicon carbide, and silicon oxycarbide.

In the foregoing semiconductor device, lots of major carriers in the lightly doped layer 215 are accumulated in the carrier accumulating layer 225. Thus, turn-on current of the MOS transistor does not decrease although an impurity concentration of the lightly doped layer 215 decreases. As a result, short channel effects of the MOS transistor are reduced by decreasing the impurity concentration of the lightly doped layer 215 and the turn-on current of the MOS transistor does not decrease due to the carrier accumulating layer 225.

Elements in the fixed charge layer 220 are segregated to the substrate surface 201 by heat. Therefore, a temperature margin increases in a subsequent process. Since the elements are accumulated in the substrate surface 201 by heat in a subsequent process, density of the elements in the fixed charge layer 220 increases. Thus, the amount of the carriers accumulated in the carrier accumulating layer 225 may increase.

Following is the description of modified versions where the fixed charge layer 220, the carrier accumulating layer 225, and the lightly doped layer 215 are applied to a flash memory cell.

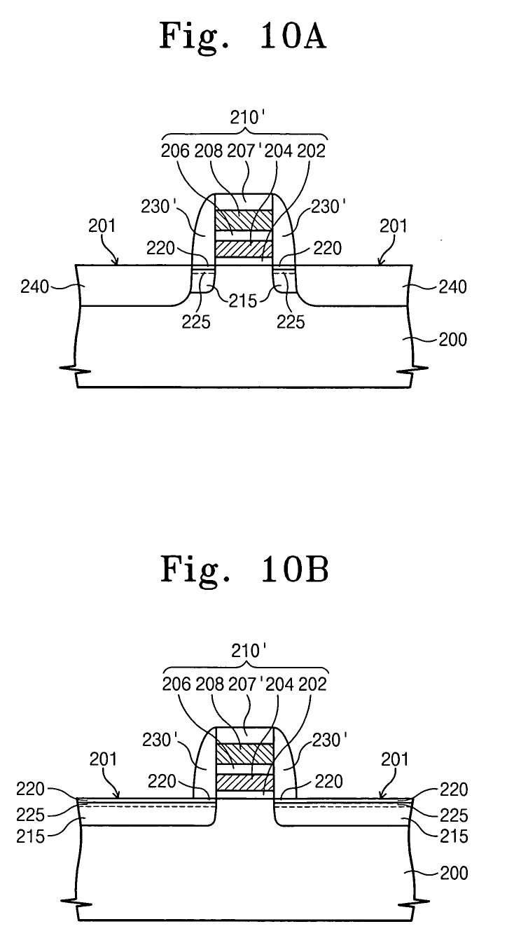

FIG. 10A is a cross-sectional view of a modified version of a semiconductor device according to the second embodiment of the present invention, and FIG. 10B is a cross-sectional view of another modified version of a semiconductor device according to the second embodiment of the present invention.

Referring to FIG. 10A and FIG. 10B, a gate pattern 210′ is disposed on a semiconductor substrate 200. The gate pattern 210′ includes a tunnel insulation layer 202, a charge storage pattern 204, a blocking insulation layer 206, a control gate electrode 208, and a capping pattern 207′, which are stacked in the order named.

A gate spacer 230′ is disposed on both sidewalls of the gate pattern 210′. A fixed charge layer 220 is disposed in a semiconductor substrate 200 below the gate spacer 230′. A lightly doped layer 215 overlapping the fixed charge layer 220 is disposed in the semiconductor substrate 200 below the gate spacer 230′. A carrier accumulating layer 225 induced by the fixed charge layer 220 is disposed at the lightly doped layer 215 below the fixed charge layer.

A heavily doped layer 240 is disposed at one side of the lightly doped layer 215 that is opposed to the gate pattern 210′. The lightly and heavily doped layers 215 and 240 correspond to a source/drain region of a flash memory cell.

Alternatively, a source/drain region of the flash memory cell may have only a lightly doped layer 215 including the carrier accumulating layer 225. In this case, the fixed charge layer 220, the carrier accumulating layer 225, and the lightly doped layer 215 extend along the substrate surface 201 in an opposite direction to the gate pattern 210′.

The tunnel insulation layer 202, the charge storage pattern 204, the blocking insulation layer 206, the control gate electrode 208, and the capping pattern 207′ may be made of the same materials as the tunnel insulation layer 102, the charge storage pattern 104, the blocking insulation layer 106, the control gate electrode 108, and the capping pattern 107′ shown in FIG. 5A, respectively.

The gate spacer 230′ may be made of the same material as the gate spacer 130a′, shown in FIG. 5A, described in the first embodiment. That is, the gate spacer 230′ may be made of insulation material having a lower dielectric constant than silicon nitride.

The flash memory cell may be applied to a flash memory device (e.g., NOR flash memory device) where charges are injected into the charge storage pattern 204 using hot carrier injection. Undoubtedly, the flash memory cell may be applied to a flash memory device where charges are injected into the charge storage pattern 204 using FN tunneling.

The foregoing flash memory cell has a carrier accumulating layer 225 in which carriers induced by the fixed charge layer 220 are accumulated. Thus, turn-on current of the flash memory cell may increase even if an impurity concentration of the lightly doped layer 215 decreases. As a result, the impurity concentration of the lightly doped layer 215 decreases more to suppress short channel effects and turn-on current increases due to the carrier accumulating layer 225.

As described above, elements in the fixed charge layer 220 are segregated to the substrate surface 201 by heat. Thus, a temperature margin of a subsequent process may increase. Since the elements are concentrated at the substrate surface 201 to increase a density of the elements in the fixed charge layer 220, carriers in the carrier accumulating layer 225 may increase more. As a result, turn-on current of the flash memory cell may increase.

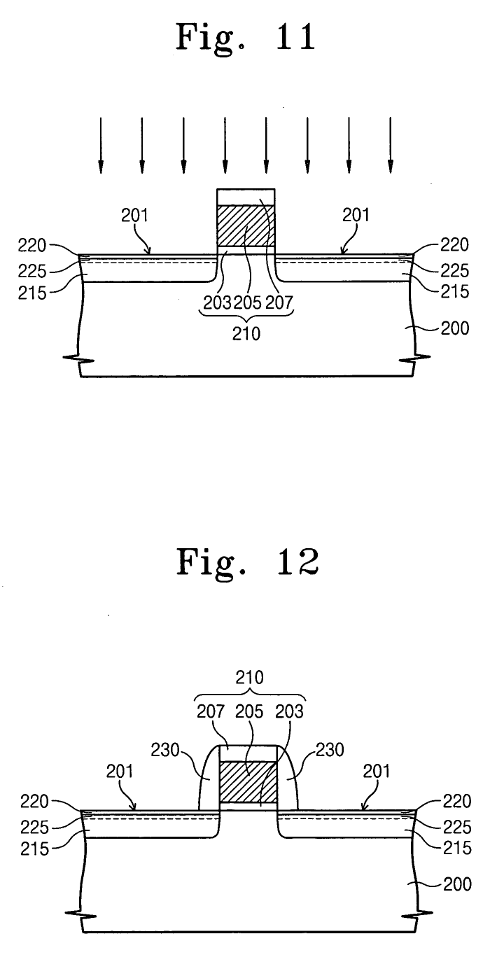

Now, a method of forming a semiconductor device will be described hereinafter more fully. FIG. 11 and FIG. 12 are cross-sectional views for explaining a method of forming a semiconductor device according to the second embodiment of the present invention.

Referring to FIG. 11, a gate pattern 210 is formed on a semiconductor substrate 200. The gate pattern 210 includes a gate insulation layer 203, a gate electrode 205, and a capping pattern 207, which are stacked in the order named. Using the gate pattern 210 as a mask, impurities of a low dose are implanted to form a lightly doped layer 215 in the semiconductor substrate 200 at opposite sides adjacent to the gate pattern 210.

Using the gate pattern 210 as a mask, element ions are implanted to form a fixed charge layer 220 at an upper portion of the lightly doped layer 210. The fixed charge layer 220 is disposed direct below a substrate surface 201. Particularly, a bottom surface of the fixed charge layer 220 is taller than that of the lightly doped layer 210.

The element ions generate negative or positive fixed charges, so that the fixed charge layer 220 is charged with the negative or positive fixed charges. The element ions are segregated to the substrate surface 201 from the inside of the semiconductor substrate 200 by heat. Charges, which charge the fixed charge layer 220, have an opposite type to major carriers of the lightly doped layer 215.

Due to formation of the fixed charge layer 220, a carrier accumulating layer 225 is induced to the lightly doped layer 215 below the fixed charge layer 220. Carriers having an opposite type to carriers of the fixed charge layer 220, i.e., major carriers of the lightly doped layer 215 are accumulated in the carrier accumulating layer 225.

The lightly doped layer 215 and the fixed charge layer 220 are sequentially formed. Particularly, the fixed charge layer 220 is formed following formation of the lightly doped layer 215. In some cases, the lightly doped layer 215 may be formed following formation of the fixed charge layer 220.

Referring to FIG. 12, a gate spacer 230 is formed on both sidewalls of the gate pattern 210. Using the gate pattern 210 and the gate spacer 230 as a mask, impurities of a high dose are implanted to form a heavily doped layer 240 shown in FIG. 9. Thus, a semiconductor device shown in FIG. 9 may be fabricated.

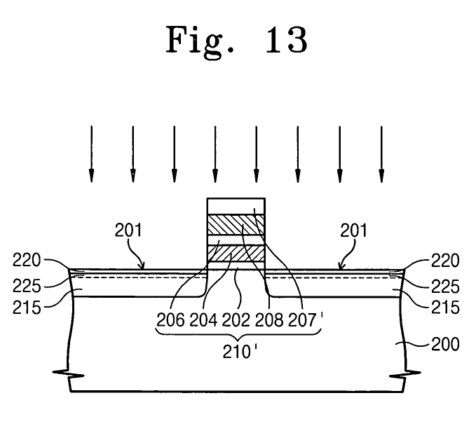

Now, modified embodiments of the present invention will be described hereinafter more fully. FIG. 13 is a cross-sectional view for explaining a method of forming modified versions of the semiconductor device according to the second embodiment of the present invention.

Referring to FIG. 13, a gate pattern 210′ is formed on a semiconductor substrate 200. The gate pattern 210′ includes a tunnel insulation layer 202, a charge storage pattern 204, a blocking insulation layer 206, a control gate electrode 208, and a capping pattern 207′, which are stacked in the order named.

Using the gate pattern 210′ as a mask, impurities of a low dose are implanted to form a lightly doped layer 215. Using the gate pattern 210′ as a mask, element ions are implanted to form a fixed charge layer 220. A carrier accumulating layer 225 induced by the fixed charge layer 220 is formed. The lightly doped layer 215, the fixed charge layer 220, and the carrier accumulating layer 225 have the same characteristics and features as described with reference to FIG. 11.

A gate spacer 230′ shown in FIG. 10B is formed on both sidewalls of the gate pattern 210′ to fabricate a semiconductor device shown in FIG. 10B.

Using the gate pattern 210′ and the gate spacer 230′ shown in FIG. 10B, impurities of a high dose are implanted to form a heavily doped layer shown in FIG. 10A. Thus, a semiconductor device shown in FIG. 10A may be fabricated.

As explained so far, a semiconductor device according to embodiments of the invention includes a fixed charge layer formed in a semiconductor substrate below a gate spacer. Due to a carrier accumulating layer or an inversion layer induced by the fixed charge layer, short channel effects of the semiconductor device are reduced. Further, turn-on current increases due to the carrier accumulating layer.

Elements in the fixed charge layer are segregated to a surface of the semiconductor substrate from the inside of the semiconductor substrate by heat. Thus, a temperature margin of a subsequent process increases. Since the elements are concentrated at the substrate surface by heat of a subsequent process, a density of the elements in the fixed charge layer increases. Thus, the amount of carriers accumulated in the inversion layer and/or the carrier accumulating layer increases.

In addition, the gate spacer is made of an insulation material having a lower dielectric constant than silicon nitride, which makes it possible to reduce a capacitance between parasitic capacitors of various shapes (e.g., a parasitic capacitor between a gate electrode and a source/drain region or a parasitic capacitor between adjacent gate electrodes). As a result, an operating speed of a semiconductor device is enhanced.

Although the present invention has been described with reference to the preferred embodiments thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

What is claimed is:

1. A semiconductor device comprising:
a gate pattern disposed on a semiconductor substrate;
a gate spacer disposed on both sidewalls of the gate pattern;
a fixed charge disposed in the semiconductor substrate below the gate spacer; and
an inversion layer disposed below the fixed charge layer, the inversion layer being induced by the fixed charge layer,
wherein elements generating fixed charges are injected into the charge storage layer and segregated to a surface of the semiconductor substrate from the inside of the semiconductor substrate by heat.

2. The semiconductor device as recited in claim 1, wherein the semiconductor substrate is doped with N-type impurities and the fixed charge layer is charged with negative charges to accumulate holes in the inversion layer, and the element is fluorine.

3. The semiconductor device as recited in claim 1, wherein the gate pattern includes a gate insulation layer and a gate electrode which are sequentially stacked on the semiconductor substrate.

4. The semiconductor device as recited in claim 3, further comprising:
an impurity-doped layer disposed at one side of the inversion layer that is opposed to the gate pattern,
wherein the inversion layer and the impurity-doped layer are electrically connected to each other.

5. The semiconductor device as recited in claim 3, wherein the spacer is made of an insulation material having a lower dielectric constant than silicon nitride.

6. The semiconductor device as recited in claim 1, wherein the gate pattern includes a tunnel insulation layer, a charge storage pattern, a blocking insulation layer, and a control gate electrode which are sequentially stacked on the semiconductor substrate.

7. The semiconductor device as recited in claim 6, further comprising:
an impurity-doped layer disposed at one side of the inversion layer that is opposed to the gate pattern,
wherein the inversion layer and the impurity-doped layer are electrically connected to each other.

8. The semiconductor device as recited in claim 6, wherein the fixed charge layer and the inversion layer extend along the surface of the semiconductor substrate in an opposite direction to the gate pattern.

9. The semiconductor device as recited in claim 6, wherein the gate spacer is made of an insulation layer having a lower dielectric constant than silicon nitride.

10. A semiconductor device comprising:
a gate pattern disposed on a semiconductor substrate;
a gate spacer disposed on both sidewalls of the gate pattern;
a fixed charge layer disposed in the semiconductor substrate below the gate spacer;
a lightly doped layer disposed in the semiconductor substrate below the gate spacer to overlap the fixed charge layer and having a lower bottom surface than the fixed charge layer; and
a carrier accumulating layer disposed at the lightly doped layer below the fixed charge layer and induced by the fixed charge layer,
wherein elements generating fixed charges are injected into the fixed charge layer and segregated to a surface of the semiconductor substrate from the inside of the semiconductor substrate.

11. The semiconductor device as recited in claim 10, wherein the semiconductor substrate is doped with N-type impurities and the lightly doped layer is doped with P-type impurities, and the fixed charge layer is charged with negative charges to accumulate holes in the carrier accumulating layer, and the element is fluorine.

12. The semiconductor device as recited in claim 10, wherein the gate pattern includes a gate insulation layer and a gate electrode which are sequentially stacked.

13. The semiconductor device as recited in claim 12, further comprising:
a heavily doped layer disposed at one side of the lightly doped layer that is opposed to the gate pattern,
wherein the lightly doped layer and the heavily doped layer are electrically connected to each other.

14. The semiconductor device as recited in claim 12, wherein the spacer is made of an insulation material having a lower dielectric constant than silicon nitride.

15. The semiconductor device as recited in claim 10, wherein the gate pattern includes a tunnel insulation layer, a charge storage pattern, a blocking insulation layer, and a control gate electrode which are sequentially stacked on the semiconductor substrate.

16. The semiconductor device as recited in claim 15, further comprising:
a heavily doped layer disposed at one side of the inversion layer that is opposed to the gate pattern,
wherein the lightly doped layer and the heavily doped layer are electrically connected to each other.

17. The semiconductor device as recited in claim 15, wherein the fixed charge layer, the carrier accumulating layer, and the lightly doped layer extend along the surface of the semiconductor substrate in an opposite direction to the gate pattern.

18. The semiconductor device as recited in claim 15, wherein the gate spacer is made of an insulation layer having a lower dielectric constant than silicon nitride.

19. A method of forming a semiconductor device, comprising:
forming a gate pattern on a semiconductor substrate, wherein the semiconductor substrate at opposite sides adjacent to the gate pattern is exposed;
injecting element ions generating fixed charges into the exposed semiconductor substrate, using the gate pattern as a mask, to form a fixed charge layer; and
forming a gate spacer on both sidewalls of the gate pattern,
wherein a layer in which carriers induced by the fixed charge is accumulated is formed below the fixed charge layer, and the elements are segregated to a surface of the semiconductor substrate from the inside of the semiconductor substrate by heat.

20. The method as recited in claim 19, wherein the fixed charge layer is charged with negative charges and the element ions are fluorine ions.

21. The method as recited in claim 19, further comprising prior to injection of elements ions:
injecting impurities of a low dose using the gate pattern as a mask.

22. The method as recited in claim 19, wherein the gate pattern includes a gate insulation layer and a gate electrode which are sequentially stacked.

23. The method as recited in claim 22, further comprising:
implanting impurities of a high dose, using the gate pattern and the gate spacer as a mask, to form a heavily doped layer.

24. The method as recited in claim 19, wherein the gate pattern includes a tunnel insulation layer, a charge storage pattern, a blocking insulation layer, and a control gate electrode which are sequentially stacked.

25. The method as recited in claim 24, further comprising:
implanting impurities of a high dose, using the gate pattern and the gate spacer as a mask, to form a heavily doped layer.

26. The method as recited in claim 19, wherein the gate spacer is made of an insulation material having a lower dielectric constant than silicon nitride.
